(19) United States
(12) Patent Application Publication
(10) Pub. No.: US 2015/0262851 A1
(43) Pub. Date: Sep. 17, 2015

(54) SEMICONDUCTOR MANUFACTURING APPARATUS

(71) Applicant: Kabushiki Kaisha Toshiba, Tokyo (JP)

(72) Inventor: Daisuke Yamashita, Kanazawa Ishikawa (JP)

(21) Appl. No.: 14/482,192

(22) Filed: Sep. 10, 2014

(30) Foreign Application Priority Data
Mar. 14, 2014 (JP) 2014-052563

(51) Int. Cl. H01L 21/67; B32B 38/10; B32B 37/14; B32B 38/00; B32B 41/00; B32B 39/00

(52) U.S. Cl. CPC H01L 21/67132; B32B 41/00; B32B 39/00; B32B 37/14; B32B 38/0004; B32B 38/10; B32B 2457/14; B32B 2405/00

(57) ABSTRACT

In one embodiment, a semiconductor manufacturing apparatus includes a cutting module configured to form, in a tape to be applied on a wafer, a slit to cut out a first tape used to protect the wafer and a second tape used to remove the first tape. The apparatus further includes an applying module configured to apply the first tape on the wafer.

### CROSS REFERENCE TO RELATED APPLICATION

This application is based upon and claims the benefit of priority from the prior Japanese Patent Application No. 2014-52563, filed on Mar. 14, 2014, the entire contents of which are incorporated herein by reference.

### FIELD

Embodiments described herein relate to a semiconductor manufacturing apparatus.

### BACKGROUND

When a discrete semiconductor device is manufactured, a back side grinding (BSG) tape is generally applied on a front side of a wafer before a back side of the wafer is polished. In this case, if the BSG tape is applied on the wafer in an outside applied state so as to protrude from the wafer, a conveyance trouble or a failure of the wafer may be caused. Therefore, the BSG tape is preferably applied on the wafer in an inside applied state so as not to protrude from the wafer. However, in the case where the BSG tape is applied on the wafer in the inside applied state, when the BSG tape is removed, a removing tape having adhesive strength stronger than the BSG tape is directly applied on a periphery of the wafer. Therefore, there is a possibility that adhesive residue of the removing tape is left on the periphery of the wafer or that the wafer is detached from an adsorption module during removing the BSG tape.

### BRIEF DESCRIPTION OF THE DRAWINGS

FIG. 1 is a plan view showing a structure of a tape applying apparatus of a first embodiment;

FIG. 2 is a sectional view showing the structure of the tape applying apparatus of the first embodiment;

FIGS. 3A to 6B are sectional views showing operations of the tape applying apparatus of the first embodiment;

FIG. 7 is a plan view showing a structure of a tape removing apparatus of the first embodiment;

FIGS. 8A to 11B are sectional views showing operations of the tape removing apparatus of the first embodiment;

FIG. 12 is a plan view showing a structure of a tape removing apparatus of a second embodiment;

FIGS. 13A to 13C are sectional views showing a first example of an operation of the tape removing apparatus of the second embodiment; and

FIGS. 14A to 14C are sectional views showing a second example of the operation of the tape removing apparatus of the second embodiment.

### DETAILED DESCRIPTION

Embodiments will now be explained with reference to the accompanying drawings.

In one embodiment, a semiconductor manufacturing apparatus includes a cutting module configured to form, in a tape to be applied on a wafer, a slit to cut out a first tape used to protect the wafer and a second tape used to remove the first tape. The apparatus further includes an applying module configured to apply the first tape on the wafer.

### First Embodiment

### (1) Tape Applying Apparatus of First Embodiment

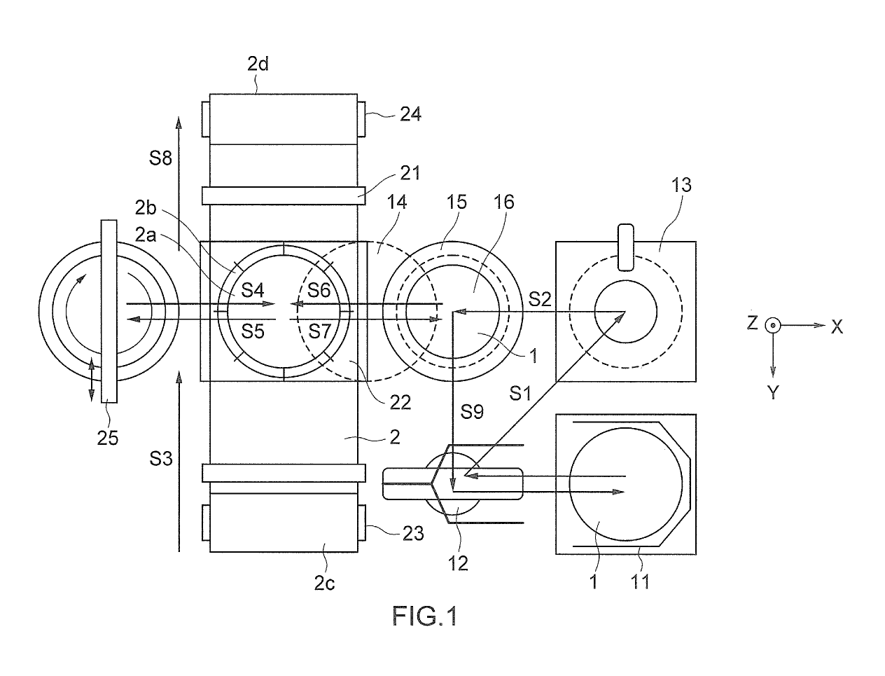

FIG. 1 is a plan view showing a structure of a tape applying apparatus of a first embodiment. The tape applying apparatus in FIG. 1 is an example of a semiconductor manufacturing apparatus.

The tape applying apparatus in FIG. 1 includes a container cassette 11, a conveyance robot 12, a notch alignment module 13, an application upper chamber 14, an application lower chamber 15, and an application stage 16. The application upper chamber 14, the application lower chamber 15, and the application stage 16 are an example of an applying module.

The tape applying apparatus in FIG. 1 further includes a tape pulling out module 21, a cutting out stage 22, an original roll core 23, a collection winding core 24, and a tape cutting module 25. The tape cutting module 25 is an example of a cutting module.

FIG. 1 shows an X direction and a Y direction which are horizontal directions perpendicular to each other, and a Z direction which is a vertical direction. In this specification, a +Z direction is handled as an upward direction, and a −Z direction is handled as a downward direction. For example, a positional relationship between the application upper chamber 14 and the application lower chamber 15 is expressed that the application lower chamber 15 is located below the application upper chamber 14.

A description of an operation of the tape applying apparatus in FIG. 1 is given below.

First, the conveyance robot 12 takes a wafer 1 out of the container cassette 11 and places the wafer 1 on the notch alignment module 13 (step S1). Next, the notch alignment module 13 performs notch alignment of the wafer 1. In FIG. 1, a surface of the wafer 1 in the +Z direction is a front side, and a surface of the wafer 1 in the −Z direction is a back side.

The conveyance robot 12 places the wafer 1 whose notch alignment is completed on the application stage 16 in the application lower chamber 15 (step S2).

The tape pulling out module 21 then pulls out a BSG tape 2, and makes the BSG tape 2 to be adsorbed to the cutting out stage 22 (step S3). The BSG tape 2 is an example of a tape to be applied on the wafer 1. A reference sign 2c denotes an original tape roll for the BSG tape 2 attached to the original roll core 23. A reference sign 2d denotes a collected tape of the BSG tape 2 attached to the collection winding core 24. When the tape pulling out module 21 is operated, the BSG tape 2 is pulled out from the original tape roll 2c and the BSG tape 2 is collected as the collected tape 2d.

The tape cutting module 25 moves onto the cutting out stage 22 to form slits in the BSG tape 2 on the cutting out stage 22 for cutting out first and second BSG tapes 2a and 2b (step S4). The tape cutting module 25 goes back to an initial position after forming the slits (step S5).

The first BSG tape 2a is used to protect the wafer 1. The first BSG tape 2a is an example of a first tape. A shape of the first BSG tape 2a in the present embodiment is a circle. In order to apply the first BSG tape 2a on the front side of the wafer 1 in an inside applied state, a diameter of the first BSG tape 2a is set smaller than a diameter of the wafer 1.

The second BSG tapes 2b are used to remove the first BSG tape 2a. The second BSG tapes 2b are an example of a second tape. A shape of each second BSG tape 2b in the present embodiment is a sector having a central angle of 45 degrees. Since the second BSG tapes 2b are adjacent to a circumference of the first BSG tape 2a, an internal diameter of each second BSG tape 2b is the same value as the diameter of the first BSG tape 2a.

The tape cutting module 25 in the present embodiment forms eight second BSG tapes 2b around one first BSG tape 2a, but the number of the second BSG tape 2b may be other than eight. The central angles of the second BSG tapes 2b may be all the same or may be different from one another.

The application upper chamber 14 moves onto the cutting out stage 22 to adsorb the first BSG tape 2a on the cutting out stage 22, and separates the first BSG tape 2a from the BSG tape 2 (step S6). At this time, the application upper chamber 14 separates the first BSG tape 2a while the second BSG tapes 2b are left in the BSG tape 2.

The application upper chamber 14 moves above the application stage 16, and vertically descends toward the wafer 1 to apply the first BSG tape 2a on the wafer 1 (step S7). At this time, the application upper chamber 14 and the application lower chamber 15 are brought into contact with each other to seal an inside of the chambers 14 and 15. In the present embodiment, the inside of the chambers 14 and 15 is evacuated (e.g., around 200 Pa) to apply the first BSG tape 2a on the wafer 1. This makes it possible to suppress air from entering between the wafer 1 and the first BSG tape 2a.

The tape pulling out module 21 then releases the BSG tape 2 from the adsorption by the cutting out stage 22, and collects the BSG tape 2 as the collected tape 2d (step S8). As a result, the second BSG tapes 2b are collected in the collected tape 2d.

The conveyance robot 12 takes the wafer 1 on which the first BSG tape 2a is applied out of the application lower chamber 15, and makes the wafer 1 be contained in the container cassette 11 (step S9).

Steps S1 to S9 in the present embodiment may be executed in an order different from the above example. For example, step S8 may be executed at the same time as step S7, or may be executed prior to step S7. Similarly, step S9 may be executed at the same time as step S8, or may be executed prior to step S8.

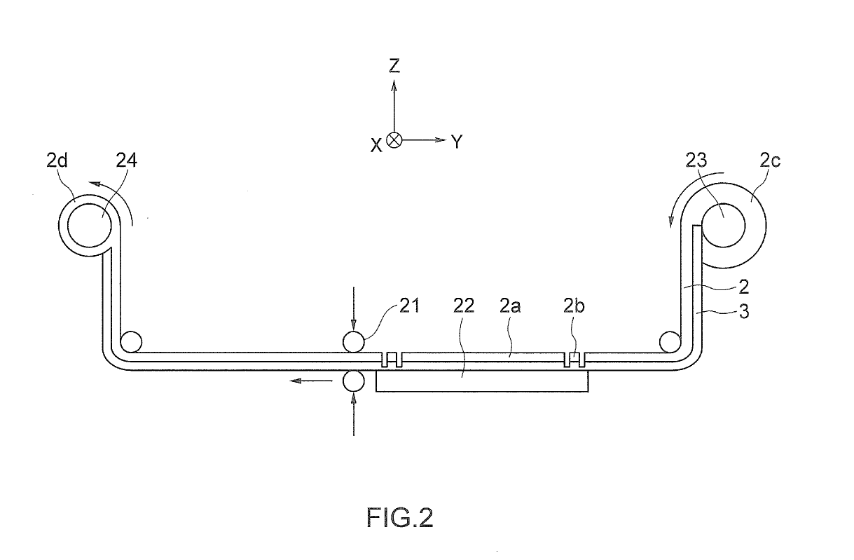

FIG. 2 is a sectional view showing the structure of the tape applying apparatus of the first embodiment.

FIG. 2 shows sections of the tape pulling out module 21, the cutting out stage 22, the original roll core 23, and the collection winding core 24. Specifically, FIG. 2 shows their sections when step S5 is finished.

Therefore, the BSG tape 2 includes the slits formed for cutting out the first and second BSG tapes 2a and 2b. A reference sign 3 denotes a liner to which the BSG tape 2 is applied. The slits of the BSG tape 2 penetrate the BSG tape 2 and reach the liner 3.

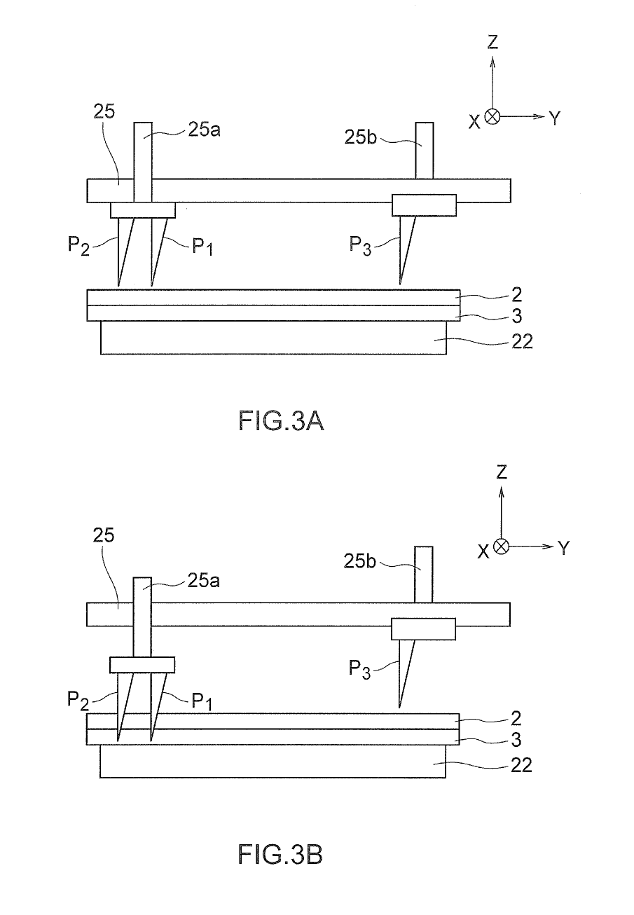

FIGS. 3A to 6B are sectional views showing operations of the tape applying apparatus of the first embodiment. A description of steps S4 to S7 described above is given in detail below with reference to FIGS. 3A to 6B.

FIG. 3A shows a section of the tape cutting module 25. The tape cutting module 25 includes a circumference cutter 25a having first and second blades P₁ and P₂, and a diameter cutter 25b having a third blade P₃. The tape cutting module 25 can drive the circumference cutter 25a to simultaneously move the first and second blades P₁ and P₂. The tape cutting module 25 can drive the diameter cutter 25b to move the third blade P₃ independently from the first and second blades P₁ and P₂. The first, second and third blades P₁, P₂ and P₃ are examples of first, second and third cutting modules, respectively.

As shown in FIG. 3A, the tape cutting module 25 moves above the BSG tape 2 on the cutting out stage 22.

The tape cutting module 25 then makes the circumference cutter 25a descend such that the circumference cutter 25a pierces the BSG tape 2 (FIG. 3B). At this time, the first and second blades P₁ and P₂ penetrate the BSG tape 2 and are made to pierce so as to reach a depth of about half a thickness of the liner 3. Therefore, the first and second blades P₁ and P₂ do not penetrate the liner 3.

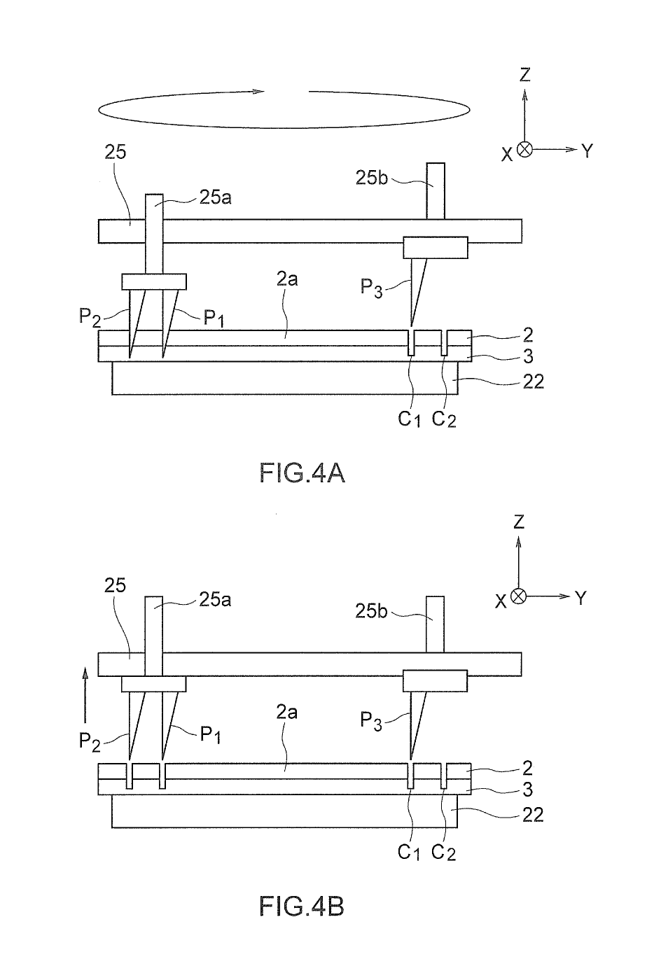

The tape cutting module 25 rotates while the circumference cutter 25a pierces the BSG tape 2 (FIG. 4A). As a result, the first and second blades P₁ and P₂ form concentric circular first and second slits C₁ and C₂ in the BSG tape 2. The first slit C₁ corresponds to the circumference of the first BSG tape 2a or inner circumferences of the second BSG tapes 2b. The second slit C₂ corresponds to outer circumferences of the second BSG tapes 2b. The first slit C₁ is an example of a first annular slit. The second slit C₂ is an example of a second annular slit surrounding the first slit.

The tape cutting module 25 elevates the circumference cutter 25a to separate the circumference cutter 25a from the BSG tape 2 (FIG. 4B).

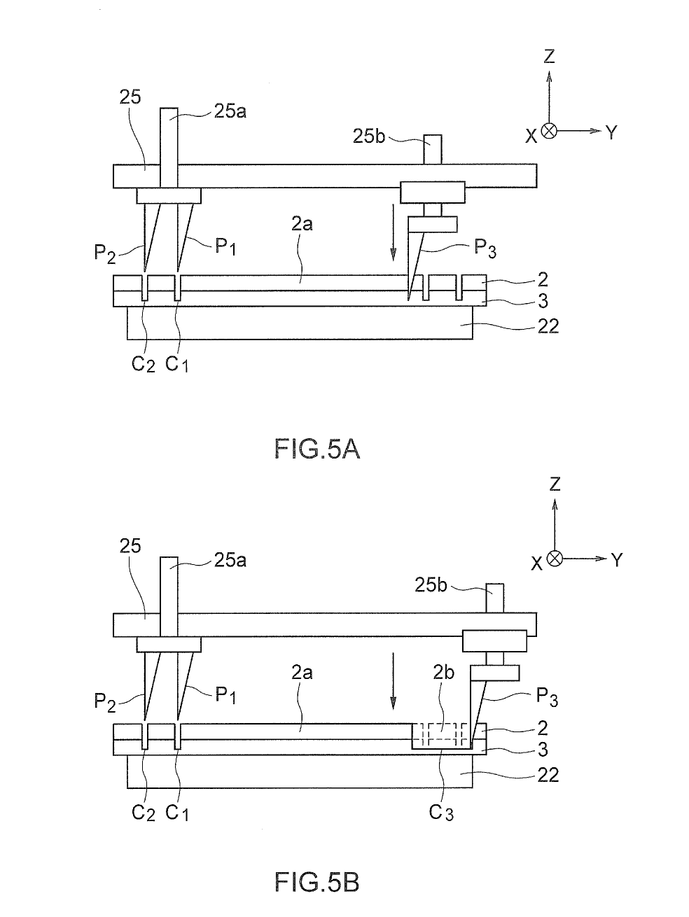

The tape cutting module 25 then makes the diameter cutter 25b descend such that the diameter cutter 25b pierces the BSG tape 2 (FIG. 5A). At this time, the third blade P₃ penetrates the BSG tape 2 and is made to pierce so as to reach a depth of about half of a thickness of the liner 3. Therefore, the third blade P₃ does not penetrate the liner 3.

The tape cutting module 25 sweeps the diameter cutter 25b in a radial direction of a rotational axis of the tape cutting module 25 while the diameter cutter 25b pierces the BSG tape 2 (FIG. 5B). The tape cutting module 25 then puts the diameter cutter 25b back to the initial position. After that, the tape cutting module 25 alternately repeats an operation of rotating around the rotational axis by 45 degrees, and the sweeping operation. As a result, the third blade P₃ forms third eight slits C₃ in a radial manner in the BSG tape 2. Each third slit C₃ corresponds to a side between the inner circumference and the outer circumference of a second BSG tape 2b. The third slits C₃ are an example of a third slit which divides a region between the first and second slits into a plurality of regions.

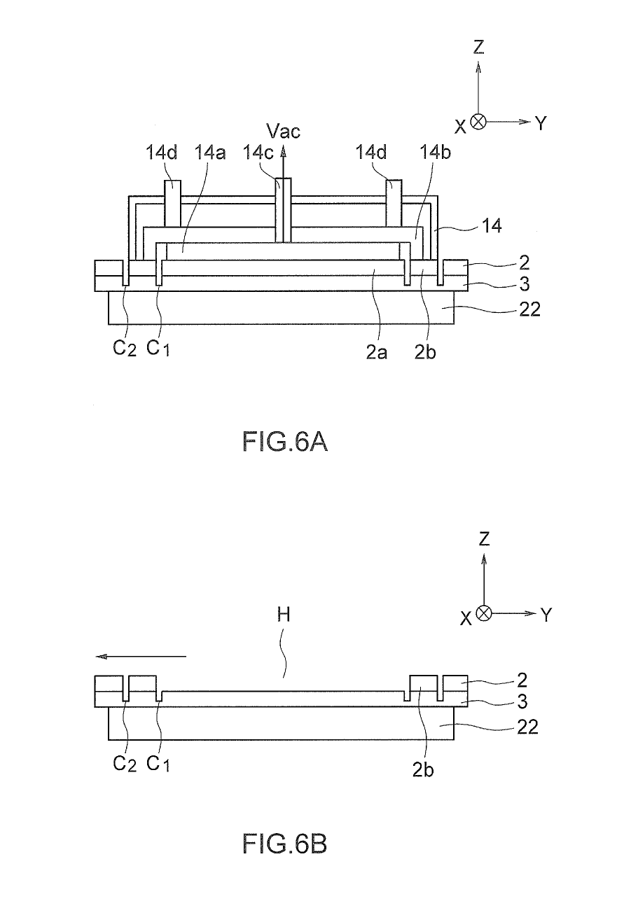

The tape cutting module 25 goes back to the initial position and the application upper chamber 14 moves above the BSG tape 2 on the cutting out stage 22 (FIG. 6A). The application upper chamber 14 includes a porous structure module 14a, a tape holding module 14b, a vacuum chuck 14c, and an up-and-down operation module 14d. The porous structure module 14a has a numerous minute pores through which air can be passed.

As shown in FIG. 6A, the application upper chamber 14 makes the porous structure module 14a descend onto the first BSG tape 2a, and covers the first BSG tape 2a and the porous structure module 14a with the tape holding module 14b. The application upper chamber 14 adsorbs the first BSG tape 2a through the porous structure module 14a by the vacuum chuck 14c to separate the first BSG tape 2a from the BSG tape 2 and the liner 3. The application upper chamber 14 moves the first BSG tape 2a onto the wafer 1 by the up-and-down operation module 14d and the like.

FIG. 6B shows the BSG tape 2 and liner 3 after the first BSG tape 2a is separated. A reference sign H denotes a hole through the BSG tape 2 obtained by separating the first BSG tape 2a. After that, the BSG tape 2 is collected as the collected tape 2d.

### (2) Tape Removing Apparatus of First Embodiment

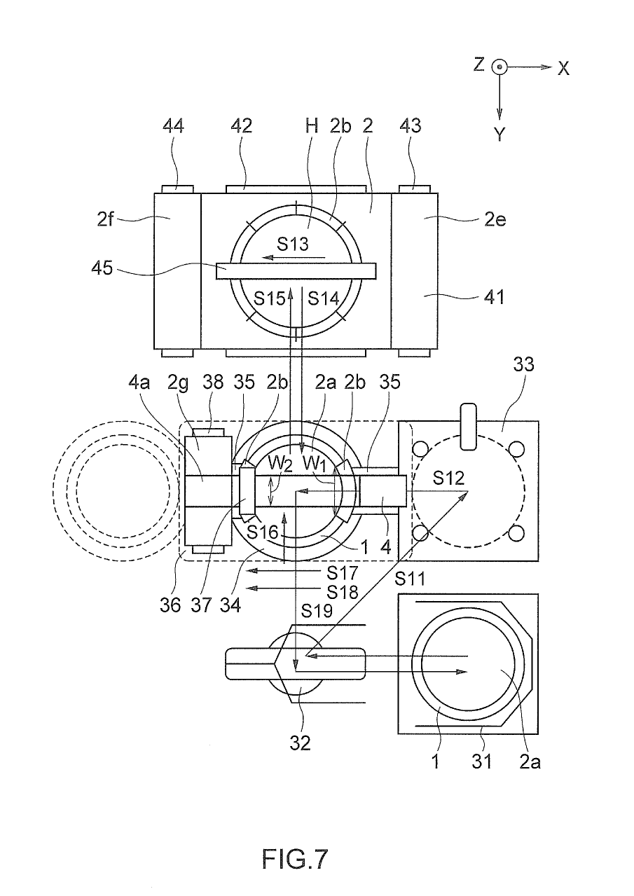

FIG. 7 is a plan view showing a structure of a tape removing apparatus of the first embodiment. The tape removing apparatus in FIG. 7 is an example of the semiconductor manufacturing apparatus.

The tape removing apparatus in FIG. 7 includes a container cassette 31, a conveyance robot 32, a notch alignment module 33, a removal stage 34, removal assisting fins 35, a tape removing module 36, an application roller 37, and a collection winding core 38. The removal assisting fins 35 are an example of a removal assisting module used to remove the first tape from the wafer. The tape removing module 36 is an example of a removing module. The application roller 37 is an example of a second applying module.

The tape removing apparatus in FIG. 7 further includes a tape supplying module 41, a tape stage 42, an original roll core 43, a collection winding core 44, and a tape applying module 45. The tape applying module 45 is an example of a first applying module.

The tape removing apparatus in FIG. 7 may be integrated with the tape applying apparatus in FIG. 1, or may be separated from the tape applying apparatus in FIG. 1.

A description of an operation of the tape removing apparatus in FIG. 7 is given below.

First, the conveyance robot 32 takes the wafer 1 out of the container cassette 31, and places the wafer 1 on the notch alignment module 33 (step S11). Next, the notch alignment module 33 performs the notch alignment of the wafer 1. In FIG. 7, the surface of the wafer 1 in the +Z direction is a front side, and the surface of the wafer 1 in the −Z direction is a back side. The first BSG tape 2a is applied on the front side of wafer 1 in the inside applied state.

The conveyance robot 32 places the wafer 1 whose notch alignment is completed on the removal stage 34 (step S12).

The tape supplying module 41 then pulls out the BSG tape 2, and makes the BSG tape 2 to be adsorbed to the tape stage 42. (step S13). A reference sign 2e denotes an original tape roll of the BSG tape 2 attached to the original roll core 43. A reference sign 2f denotes a collected tape of the BSG tape 2 attached to the collection winding core 44. When the tape supplying module 41 is operated, the BSG tape 2 is pulled out from the original tape roll 2e and the BSG tape 2 is collected as the collected tape 2f.

In the present embodiment, the original tape roll 2e in FIG. 7 is the same tape as the collected tape 2d in FIG. 1. For example, the original tape roll 2e is prepared by detaching the collected tape 2d from the collection winding core 24 to attach the collected tape 2d to the original roll core 43. Therefore, the BSG tape 2 in FIG. 7 includes the second BSG tapes 2b and the hole H surrounded by the second BSG tapes 2b.

The tape applying module 45 adsorbs second BSG tapes 2b, and moves onto the removal stage 34 to apply the second BSG tapes 2b on the wafer 1 and the removal assisting fins 35 (step S14). The removal assisting fins 35 are arranged at positions so as to sandwich the wafer 1 on the removal stage 34 in order to attenuate the level difference between the wafer 1 and the removal stage 34. The tape applying module 45 in the present embodiment applies each second BSG tape 2b so as to form a bridge between a periphery of the wafer 1 at which the first BSG tape 2a is not applied and a removal assisting fin 35. After that, the tape applying module 45 goes back to the initial position (step S15).

The tape removing module 36 then descends onto the removal stage 34 to bring an adhesive face of a removing tape 4 into contact with the first or second BSG tape 2a or 2b on the wafer 1 (step S16). The removing tape 4 is an example of a third tape.

The tape removing module 36 makes the removal stage 34 slide in the −X direction while compressing the removing tape 4 by the application roller 37 (step S17). As a result, the removing tape 4 is applied on the first and second BSG tapes 2a and 2b on the wafer 1, and on the removal assisting fins 35. The application roller 37 in the present embodiment applies the removing tape 4 so as to form bridges between the first and second BSG tapes 2a and 2b on the wafer 1 and the removal assisting fins 35. After that, the removal stage 34 goes back to the initial position.

A width W₁ of an inner circumference portion of each second BSG tape 2b in the present embodiment is set to be longer than a width W₂ of the removing tape 4. The width W₁ of the inner circumference portion of each second BSG tape 2b is a distance between one end and the other end on the inner circumference of each second BSG tape 2b. According to the present embodiment, the width W₁ is set longer than the width W₂ such that the removing tape 4 can be applied on the first and second BSG tapes 2a and 2b and the removal assisting fin 35 such that the removing tape 4 is out of contact with the wafer 1.

The tape removing module 36 compresses the removing tape 4 by the application roller 37 while sliding the removal stage 34 in the −X direction (step S18). At this time, the collection winding core 38 rotates at the same speed as the removal stage 34. As a result, the removing tape 4 is removed from the wafer 1, and the first and second BSG tapes 2a and 2b are also removed together with the removing tape 4 from the wafer 1. After that, the removing tape 4 is collected around the collection winding core 38 as a collected tape 4a, and the first and second BSG tapes 2a and 2b are also collected around the collection winding core 38 as a collected tape 2g. After that, the removal stage 34 goes back to the initial position.

The conveyance robot 12 then takes the wafer 1 from which the first BSG tape 2a is removed out of the removal stage 34, and makes the wafer 1 be contained in the container cassette 31 (step S19).

Steps S11 to S19 in the present embodiment may be executed in an order different from the above example. For example, step S15 may be executed at the same time as step S16.

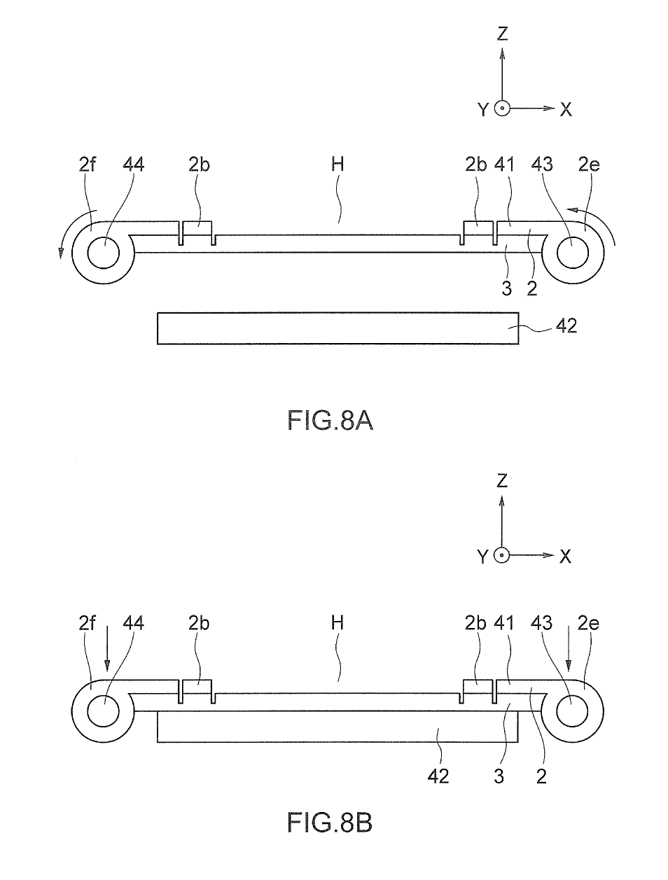

FIGS. 8A to 11B are sectional views showing operations of the tape removing apparatus of the first embodiment. A description of steps S13 to S15 described above is given in detail below with reference to FIGS. 8A to 11B.

The tape supplying module 41 pulls out the BSG tape 2 until the second BSG tape 2b appears above the tape stage 42 (FIG. 8A).

The tape supplying module 41 descends onto the tape stage 42 (FIG. 8B). As a result, the liner 3 for the BSG tape 2 is brought into contact with the tape stage 42. The BSG tape 2 and the liner 3 are adsorbed by the tape stage 42.

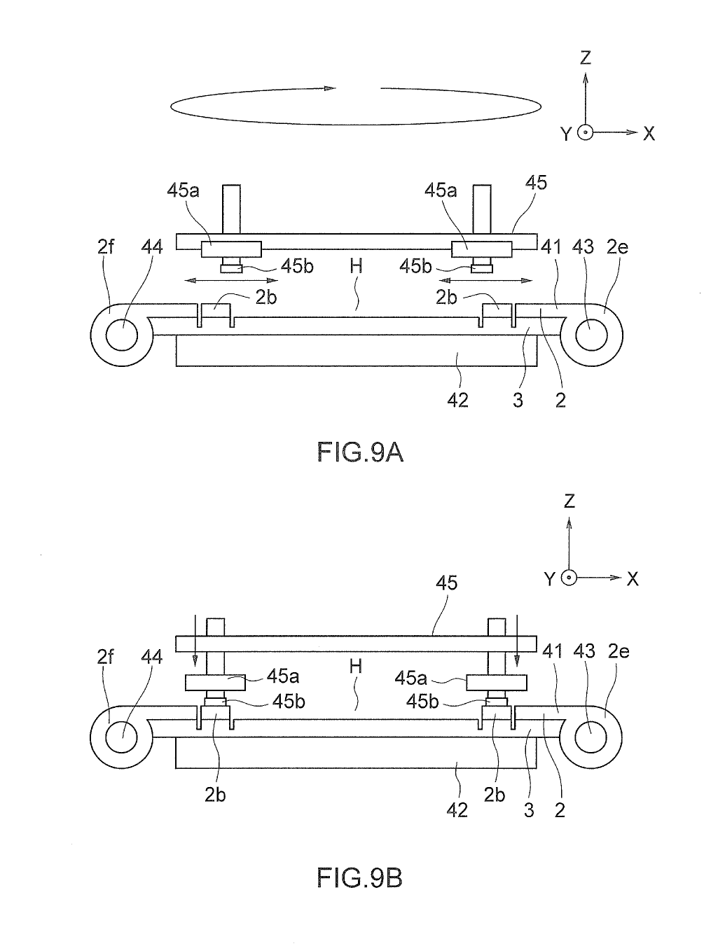

The tape applying module 45 then moves above the tape stage 42 (FIG. 9A). The tape applying module 45 includes two sets of adsorption hand 45a and adsorption pad 45b. As shown by arrows in FIG. 9A, the adsorption hands 45a can perform a rotating operation and sliding operations. The tape applying module 45 aligns in-plane positions of the adsorption pads 45b and the second BSG tapes 2b by using an unshown alignment module. For example, the alignment module may perform the alignment by specifying coordinates by using size information specified in a process recipe, or may perform the alignment by way of image recognition alignment by using a CCD camera. The adsorption pads 45b have sizes smaller than the second BSG tapes 2b and have shapes that each side of the adsorption pads 45b is smaller by about 1 mm than that of the second BSG tapes 2b, for example.

The tape applying module 45 makes the adsorption hands 45a descend to bring the adsorption pads 45b into contact with the second BSG tapes 2b (FIG. 9B). The adsorption pads 45b adsorb the second BSG tapes 2b by way of vacuum adsorption.

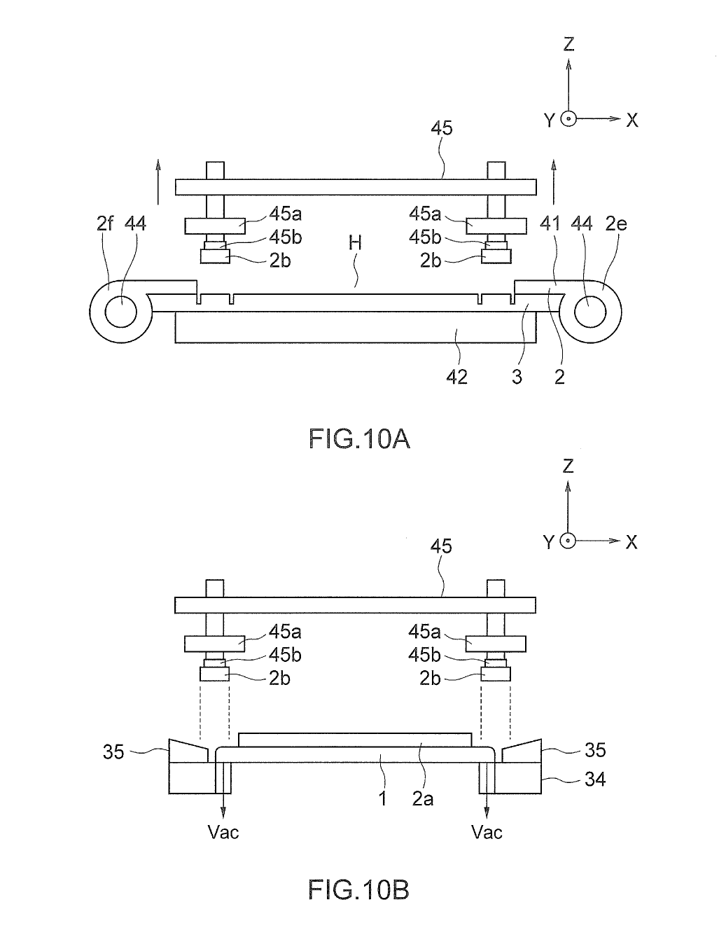

The tape applying module 45 ascends above the tape stage 42 to separate the second BSG tapes 2b from the BSG tape 2 (FIG. 10A). The tape applying module 45 in the present embodiment can simultaneously transfer two second BSG tapes 2b as shown in FIG. 10A.

The tape applying module 45 moves above the wafer 1 on the removal stage 34 (FIG. 10B). The tape applying module 45 aligns in-plane positions of the periphery of the wafer 1 and the adsorption pads 45b by using the alignment module described above. The removal stage 34 adsorbs the wafer 1 by way of vacuum adsorption.

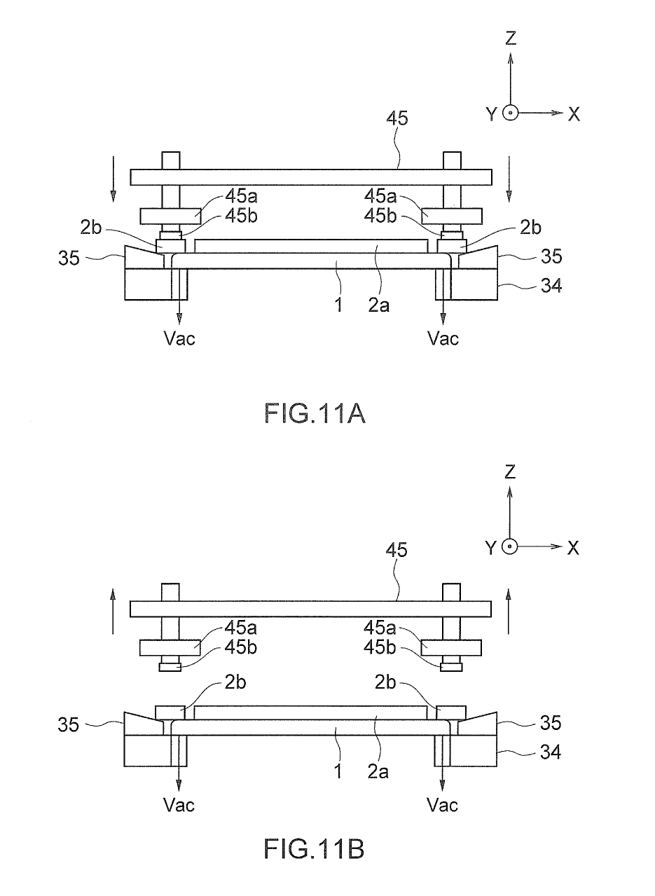

The tape applying module 45 descends onto the wafer 1 to bring the second BSG tapes 2b into contact with the periphery of the wafer 1 and the removal assisting fins 35 (FIG. 11A).

The tape applying module 45 then releases the adsorption of the second BSG tapes 2b involved by the adsorption pads 45b, and ascends above the wafer 1 (FIG. 11B). In this way, the second BSG tapes 2b are applied at the periphery of the wafer 1 and the removal assisting fins 35.

In the present embodiment, the second BSG tapes 2b are applied so as to form bridges between the wafer 1 and the removal assisting fins 35 such that compression amounts of the adsorption pads 45b can be decreased in applying the second BSG tapes 2b. Therefore, according to the present embodiment, a load on the periphery of the wafer 1 owing to the adsorption pads 45b can be restrained to prevent the wafer 1 from breaking.

### (3) Details of Tape Applying Apparatus and Tape Removing Apparatus of First Embodiment

A description of the tape applying apparatus in FIG. 1 and the tape removing apparatus in FIG. 7 is given in detail.

As described above, the tape applying apparatus forms the slits to cut out the first and second BSG tapes 2a and 2b in the BSG tape 2, and applies the first BSG tape 2a on the wafer 1.

Also, the tape removing apparatus applies the second BSG tapes 2b on the wafer 1 to which the first BSG tape 2a is applied and on the removal assisting fins 35, and applies the removing tape 4 on the first and second BSG tapes 2a and 2b on the wafer 1 and on the removal assisting fins 35 to remove the first and second BSG tapes 2a and 2b together with the removing tape 4.

Therefore, the present embodiment makes it possible to remove the first BSG tape 2a from the wafer 1 without directly applying the removing tape 4 on the wafer 1. Therefore, the present embodiment makes it possible to prevent the adhesive residue of the removing tape 4 from being left on the wafer 1.

The first and second BSG tapes 2a and 2b in the present embodiment are cut out from the same BSG tape 2. Therefore, the present embodiment makes it possible to cut out the second BSG tapes 2b for the removal assisting from the BSG tape 2 to be discarded, thereby suppressing material cost for the BSG tape 2.

The width W₁ of the inner circumference portion of each second BSG tape 2b in the present embodiment is set longer than the width W₂ of the removing tape 4. Therefore, the present embodiment makes it possible to apply the removing tape 4 on the first and second BSG tapes 2a and 2b and the removal assisting fins 35 while the removing tape 4 is out of contact with the wafer 1.

However, if the removing tape 4 can be set to be out of contact with the wafer 1, the width W₁ of the inner circumference portion of each second BSG tape 2b may be set shorter than the width W₂ of the removing tape 4. For example, if plural second BSG tapes 2b are applied near one removal assisting fin 35, the removing tape 4 can be set to be out of contact with the wafer 1 even though the width W₁ is shorter than the width W₂.

The removal assisting fins 35 in the present embodiment are preferably made from material facilitating the removal of the second BSG tapes 2b and the removing tape 4. An example of such a material is polytetrafluoroethylene (PEFE). Regarding the removal assisting fins 35 in the present embodiment, only portions in contact with the second BSG tapes 2b or the removing tape 4 may be made of PTFE, or the front sides of them may be coated with PTFE.

The removal stage 34 in the present embodiment adsorbs the back side of the wafer 1 around the periphery by way of vacuum adsorption. Such an adsorption method has an advantage that the wafer 1 can be adsorbed without a back side electrode of the wafer 1 being contacted, but has a disadvantage that adsorption power for the wafer 1 is weak. If the adsorption power for the wafer 1 is weak, there is a possibility that the wafer 1 is detached from the removal stage 34 during removing the first BSG tape 2a. However, the present embodiment makes it possible to prevent the wafer 1 from being detached because the first BSG tape 2a can be easily removed.

### Second Embodiment

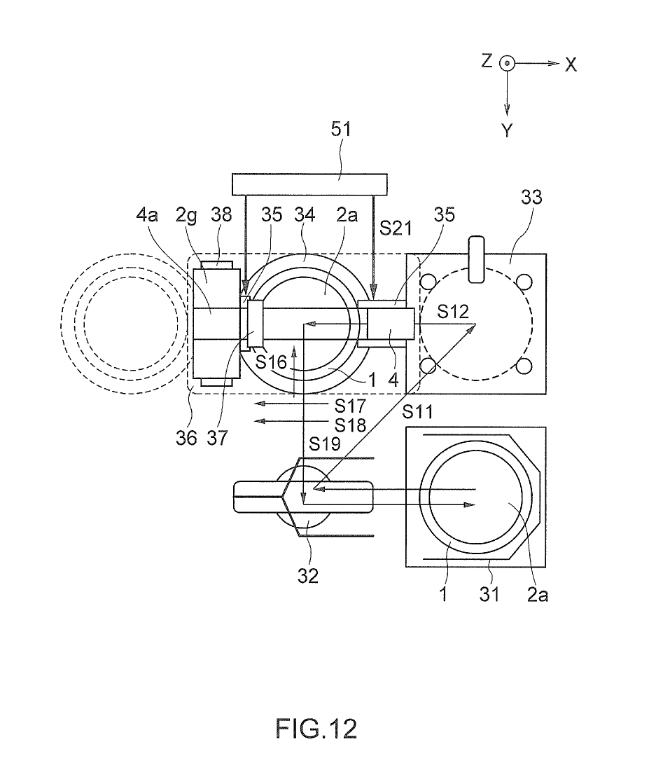

FIG. 12 is a plan view showing a structure of a tape removing apparatus of a second embodiment. The tape removing apparatus in FIG. 12 is an example of the semiconductor manufacturing apparatus.

The tape removing apparatus in FIG. 12 includes the container cassette 31, the conveyance robot 32, the notch alignment module 33, the removal stage 34, the removal assisting fins 35 as an example of the removal assisting module, the tape removing module 36 as an example of the removing module, the application roller 37 as an example of an applying module, the collection winding core 38, and a height adjusting module 51 as an example of an adjusting module.

The height adjusting module 51 adjusts the positions of the removal assisting fins 35 such that a height of an upper face of the first BSG tape 2a on the wafer 1 matches heights of upper faces of the removal assisting fins 35. Therefore, the tape removing apparatus in the present embodiment can make the removing tape 4 be out of contact with the wafer 1 even if the removing tape 4 is applied without using the second BSG tapes 2b.

The tape removing apparatus in FIG. 12 may be integrated with the tape applying apparatus in FIG. 1, or may be separated from the tape applying apparatus in FIG. 1. However, the tape applying apparatus in FIG. 1 in these cases may not have the function to form the second BSG tapes 2b. Specifically, this tape applying apparatus may not include the diameter cutter 25b.

In the present embodiment, the first BSG tape 2a is an example of a first tape, and the removing tape 4 is an example of a second tape.

A description of an operation of the tape removing apparatus in FIG. 12 is given below.

First, the conveyance robot 32 takes the wafer 1 out of the container cassette 31, and places the wafer 1 on the notch alignment module 33 (step S11). Next, the notch alignment module 33 performs the notch alignment of the wafer 1. The first BSG tape 2a is applied on the front side of the wafer 1 (the surface in the +Z direction) in the inside applied state.

The conveyance robot 32 places the wafer 1 whose notch alignment is completed on the removal stage 34 (step S12).

The height adjusting module 51 then adjusts the heights of the upper faces of the removal assisting fins 35 to be equal to the height of the upper face of the first BSG tape 2a on the wafer 1 (step S21).

The tape removing module 36 descends onto the removal stage 34 to bring the adhesive face of the removing tape 4 into contact with the first BSG tape 2a on the wafer 1 (step S16). At this time, the adhesive face of the removing tape 4 is out of contact with the front side of the wafer 1.

The tape removing module 36 slides the removal stage 34 in the −X direction while compressing the removing tape 4 by the application roller 37 (step S17). As a result, the removing tape 4 is applied on the first BSG tape 2a on the wafer 1 and the removal assisting fins 35. After that, the removal stage 34 goes back to the initial position.

The tape removing module 36 compresses the removing tape 4 by the application roller 37 while sliding the removal stage 34 in the −X direction (step S18). At this time, the collection winding core 38 rotates at the same speed as the removal stage 34. As a result, the removing tape 4 is removed from the wafer 1, and the first BSG tape 2a is also removed together with the removing tape 4 from the wafer 1. After that, the removing tape 4 is collected around the collection winding core 38 as the collected tape 4a, and the first BSG tape 2a is also collected around the collection winding core 38 as the collected tape 2g. After that, the removal stage 34 goes back to the initial position.

The conveyance robot 12 then takes the wafer 1 from which the first BSG tape 2a is removed out of the removal stage 34, and makes it be contained in the container cassette 31 (step S19).

Step S11, S12, S21 and S16 to S19 in the present embodiment may be executed in an order different from the above example.

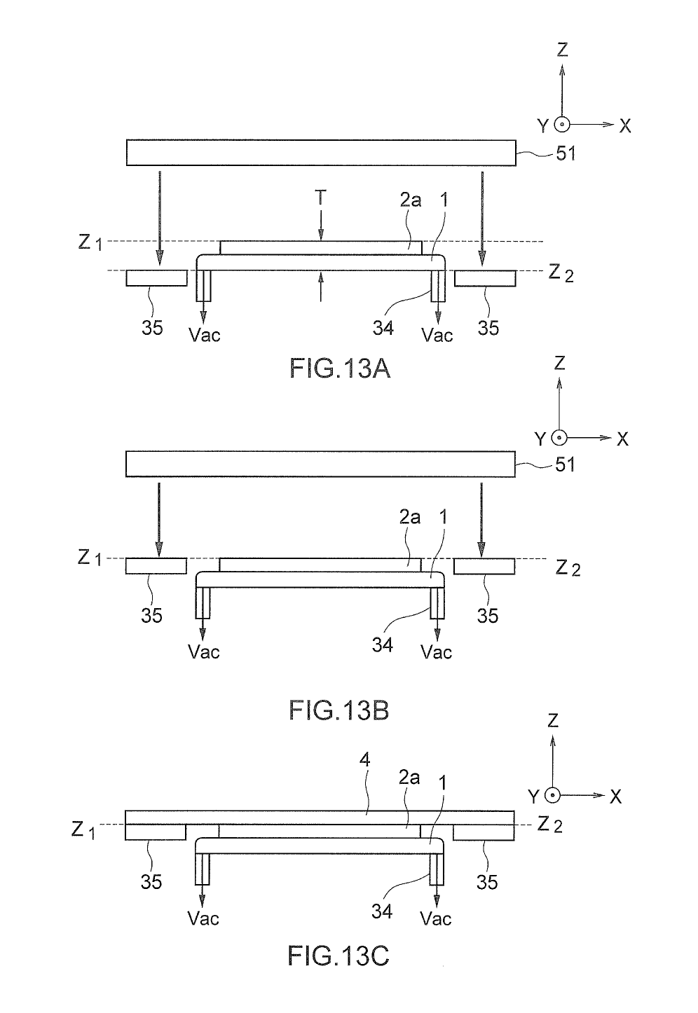

FIGS. 13A to 13C are sectional views showing a first example of the operation of the tape removing apparatus of the second embodiment. FIGS. 13A to 13C show details of step S21, S16 and S17 described above.

The tape removing apparatus of the first example can hold a work thickness T as a removal process recipe for the first BSG tape 2a (FIG. 13A). The work thickness T is a total thickness of the wafer 1 and first BSG tape 2a.

A reference sign Z₁ denotes the height of the upper face of the first BSG tape 2a on the wafer 1. A reference sign Z₂ denotes the height of the upper faces of the removal assisting fins 35. The height Z₂ of the upper faces of the removal assisting fins 35 in FIG. 13A matches a height of an upper face of the removal stage 34. The height adjusting module 51 deals with the height Z₂ in this case as a reference height.

The height adjusting module 51 elevates the removal assisting fins 35 in FIG. 13A by the work thickness T (FIG. 13B). As a result, the height Z₂ of the upper faces of the removal assisting fins 35 is adjusted to the height Z₁ of the upper face of the first BSG tape 2a on the wafer 1. The height adjusting module 51 in the present embodiment moves the removal assisting fins 35 up and down by use of a pulse motor.

The tape removing module 36 and the application roller 37 apply the removing tape 4 on the first BSG tape 2a on the wafer 1 and on the removal assisting fins 35 (FIG. 13C). The tape removing apparatus in the present embodiment matches the height Z₁ to the height Z₂ such that the removing tape 4 can be applied on the first BSG tape 2a and on the removal assisting fins 35 without directly applying the removing tape 4 on the wafer 1 (FIG. 13C). In other words, the present embodiment makes it possible to apply the removing tape 4 in a tinting application state.

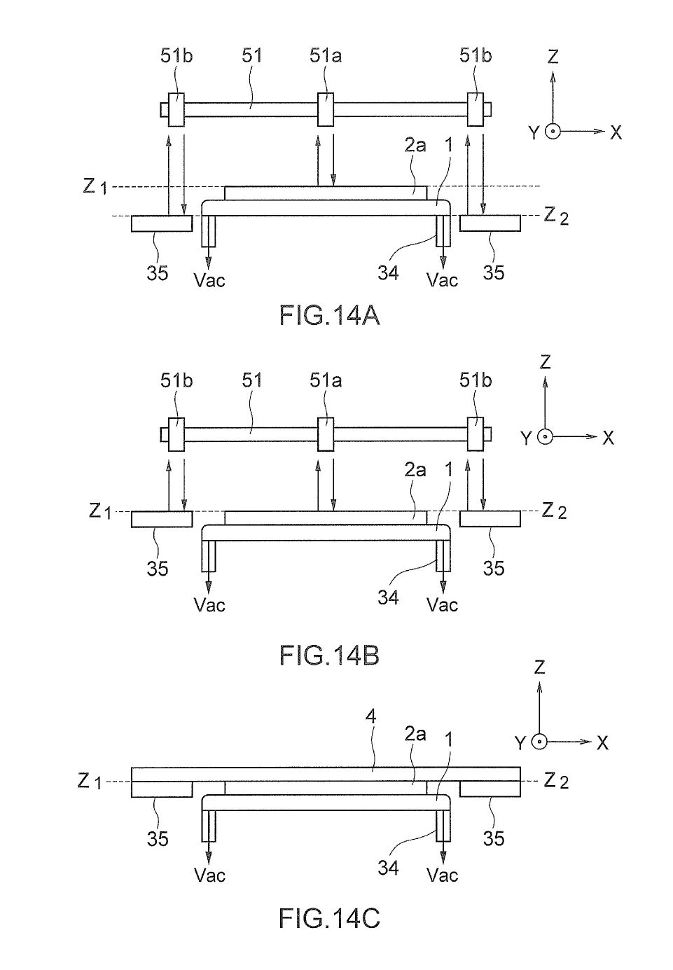

FIGS. 14A to 14C are sectional views showing a second example of the operation of the tape removing apparatus in the second embodiment. FIGS. 14A to 14C show details of step S21, S16 and S17 described above.

The height adjusting module 51 of the second example includes first and second laser displacement meters 51a and 51b (FIG. 14A). The first laser displacement meter 51a measures a distance between the upper face of the first BSG tape 2a on the wafer 1 and the height adjusting module 51. The second laser displacement meter 51b measures a distance between the upper faces of the removal assisting fins 35 and the height adjusting module 51.

The height adjusting module 51 elevates the removal assisting fins 35 in FIG. 14A (FIG. 14B) such that a difference between the distances measured by the first and second laser displacement meters 51a and 51b becomes zero. As a result, the height Z₂ of the upper faces of the removal assisting fins 35 is adjusted to the height Z₁ of the upper face of the first BSG tape 2a on the wafer 1.

The tape removing module 36 and the application roller 37 then apply the removing tape 4 on the first BSG tape 2a on the wafer 1 and on the removal assisting fin 35 (FIG. 14C). This is similar to the case of the first example.

The height adjusting module 51 of the second example measures the distance described above by the first and second laser displacement meters 51a and 51b. However, the height adjusting module 51 may measure it by other means (e.g., a CCD camera). The height adjusting module 51 of the second example measures the distance described above by an optical methodology. However, the height adjusting module 51 may measure by other methodologies (e.g., an acoustic methodology or an electromagnetic methodology).

The tape removing apparatus in the present embodiment may use the operations of the first and second examples in combination with each other. For example, the tape removing apparatus in the present embodiment may adjust roughly the height of the removal assisting fins 35 according to the first example, and thereafter may finely adjust the height of the removal assisting fins 35 according to the second example.

As described above, the tape removing apparatus in the present embodiment matches the height Z₁ of the upper face of the first BSG tape 2a on the wafer 1 to the height Z₂ of the upper faces of the removal assisting fins 35, and thereafter applies the removing tape 4 on the first BSG tape 2a on the wafer 1 and on the removal assisting fin 35.

Therefore, the present embodiment makes it possible to remove the first BSG tape 2a from the wafer 1 without directly applying the removing tape 4 on the wafer 1. Therefore, the present embodiment makes it possible to prevent the adhesive residue of the removing tape 4 from being left on the wafer 1.

As described above, according to the first and second embodiments, the first BSG tape 2a applied on the wafer 1 can be easily removed.

While certain embodiments have been described, these embodiments have been presented by way of example only, and are not intended to limit the scope of the inventions. Indeed, the novel apparatuses described herein may be embodied in a variety of other forms; furthermore, various omissions, substitutions and changes in the form of the apparatuses described herein may be made without departing from the spirit of the inventions. The accompanying claims and their equivalents are intended to cover such forms or modifications as would fall within the scope and spirit of the inventions.

1. A semiconductor manufacturing apparatus comprising:
a cutting module configured to form, in a tape to be applied on a wafer, a slit to cut out a first tape used to protect the wafer and a second tape used to remove the first tape; and
an applying module configured to apply the first tape on the wafer.

2. The apparatus of claim 1, wherein the cutting module includes:
a first cutting module configured to form a first annular slit in the tape,
a second cutting module configured to form, in the tape, a second annular slit surrounding the first slit, and
a third cutting module configured to form, in the tape, a third slit dividing a region between the first and second slits into a plurality of regions.

3. The apparatus of claim 2, wherein the cutting module simultaneously moves the first and second cutting modules to form the first and second slits.

4. The apparatus of claim 2, wherein the cutting module rotates the first cutting module to form the first slit, and rotates the second cutting module to form the second slit.

5. The apparatus of claim 4, wherein the cutting module moves the third cutting module in a radial direction of a rotational axis of the first and second cutting modules to form the third slit.

6. The apparatus of claim 2, wherein the cutting module is capable of moving the third cutting module independently from the first and second cutting modules.

7. The apparatus of claim 1, wherein the applying module adsorbs the first tape to separate the first tape from the tape, and applies the separated first tape on the wafer.

8. The apparatus of claim 7, wherein the applying module separates the first tape from the tape while the second tape is left in the tape.

9. The apparatus of claim 7, wherein the applying module includes a member including a plurality of pores, and an adsorption module configured to adsorb the first tape through the member.

10. The apparatus of claim 1, wherein a shape of the first tape is a circle, and a shape of the second tape is a sector.

11. A semiconductor manufacturing apparatus comprising:
a first applying module configured to apply a second tape on a wafer on which a first tape is applied, and on a removal assisting module used to remove the first tape from the wafer;
a second applying module configured to apply a third tape on the first and second tapes on the wafer, and on the removal assisting module; and
a removing module configured to remove the first and second tapes from the wafer by removing the third tape from the wafer.

12. The apparatus of claim 11, wherein the first and second tapes are cut out from the same tape.

13. The apparatus of claim 11, wherein the first applying module adsorbs the second tape to separate the second tape from the tape, and applies the separated second tape on the wafer and on the removal assisting module.

14. The apparatus of claim 11, wherein the first applying module adsorbs the second tape by an adsorption pad having a shape smaller than the second tape.

15. The apparatus of claim 11, wherein the second applying module applies the third tape on the first and second tapes on the wafer and on the removal assisting module such that the third tape is out of contact with the wafer.

16. The apparatus of claim 11, wherein a width of the second tape is larger than a width of the third tape.

17. A semiconductor manufacturing apparatus comprising:
an adjusting module configured to adjust a position of a removal assisting module such that a height of an upper face of a first tape on a wafer matches a height of an upper face of the removal assisting module, the removal assisting module being configured to remove the first tape from the wafer; and
an applying module configured to apply a second tape on the first tape on the wafer and on the removal assisting module after the position of the removal assisting module is adjusted; and
a removing module configured to remove the first tape from the wafer by removing the second tape from the wafer.

18. The apparatus of claim 17, wherein the applying module applies the second tape on the first tape on the wafer and on the removal assisting module such that the second tape is out of contact with the wafer.

19. The apparatus of claim 17, wherein the adjusting module adjusts the position of the removal assisting module, based on a total thickness of the wafer and the first tape.

20. The apparatus of claim 17, wherein the adjusting module measures first data indicating the height of the upper face of the first tape, measures second data indicating the height of the upper face of the removal assisting module, and adjusts the position of the removal assisting module based on the first and second data.
